(19) United States
(12) Patent Application Publication
(10) Pub. No.: US 2010/0289508 A1
(43) Pub. Date: Nov. 18, 2010

(54) ELECTRONIC ANALYSIS CIRCUIT WITH ALTERNATION OF CAPACITIVE/RESISTIVE MEASUREMENT FOR PASSIVE-MATRIX MULTICONTACT TACTILE SENSOR

(75) Inventors: Pascal Joguet, Sadirac (FR); Guillaume Largillier, Bordeaux (FR); Julien Olivier, Bordeaux (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: Stantum, Bordeaux (FR)

(21) Appl. No.: 12/809,434

(22) PCT Filed: Dec. 19, 2008
(86) PCT No.: PCT/FR2008/001805

§ 371 Date: Jun. 18, 2010

(30) Foreign Application Priority Data
Dec. 19, 2007 (FR) 0760015

(51) Int. Cl. G01R 27/26

(52) U.S. Cl. 324/686

(57) ABSTRACT

An electronic analysis circuit for a passive-matrix multicontact tactile sensor including an electrical supply mechanism feeding one of two axes of the matrix, and a mechanism for detecting electrical characteristics along the other axis of the matrix, at intersections between the two axes. The electrical characteristic measured is alternately capacitance and resistance. A multicontact passive-matrix tactile sensor includes an electrical supply mechanism feeding one of the two axes of the matrix, a mechanism detecting electrical characteristics along the other axis of the matrix, at the intersections between the two axes, and such an electronic analysis circuit.

The present invention concerns an electronic analysis circuit with alternation of capacitance and resistance measurement for passive-matrix multicontact tactile sensors.

The present invention concerns the field of passive-matrix multicontact tactile sensors.

This type of sensor is provided with means for simultaneous acquisition of the position, the pressure, the size, the shape and the movement of a plurality of fingers on its surface in order to control equipment, preferably via a graphical interface.

Said sensors can be used as interfaces for personal computers, portable or not, cellular telephones, automatic teller machines (banks, points of sale, ticket sales), gaming consoles, portable multimedia players (digital walkman), control of audiovisual equipment or electrical domestic appliances, control of industrial equipment, GPS navigators. This list is not limiting on the present invention.

Transparent multicontact tactile sensors are known in the art. Such a sensor consists of a tactile interaction surface featuring two non-parallel arrays. Each array consists of a set of generally parallel tracks. These arrays define between them nodes situated at the projection of the intersection of one array on the other. Physical measurement means are provided at these nodes to deliver information that is a function of the presence on the corresponding contact area.

These sensors make it possible to find out the state of a plurality of contact areas simultaneously. The measurement effected at each node corresponds to a measurement of voltage or of capacitance at the terminals of the two array elements associated with the node concerned. Each array is scanned sequentially and quickly in order to create an image of the sensor several times per second.

In order to achieve a suitable response time, it is imperative to be able to measure the activity of a finger with a maximum latency time of 20 milliseconds.

There has been proposed in the prior art a solution described in the patent FR 2,866,726 covering a device for controlling virtual graphic objects on a multicontact tactile display by manipulating them.

Said device further comprises an analysis electronic circuit making it possible to acquire and to analyze data from the sensor with a sampling frequency of 100 hertz. The sensor may be divided into a plurality of areas in order to effect parallel processing in said areas. It includes a matrix of conductive tracks, said matrix including energization means on one of the two axes and on the other axis means for detection of electrical characteristics at the intersection between the two axes.

The electrical characteristic actually measured can be either resistance or capacitance. Resistive or capacitive sensors, respectively, are then referred to.

The choice of an electrical characteristic between resistance and capacitance generates drawbacks that render the solution adopted unsuitable for various applications. More particularly, measurement of capacitance restricts contact to fingers—or other objects specific to capacitive sensors—at the same time as offering improved contact sensitivity, the presence of a finger being measurable before it has physically touched the sensor. The measurement of resistance offers lower sensitivity but accommodates any type of contact object, finger, stylus or any object coming into contact with the surface of the sensor.

The choice of one or the other of these two electrical characteristics makes it impossible to obtain a passive-matrix multipoint tactile sensor having sufficient sensitivity as well as a panel of available contact elements.

The object of the present invention is to remedy this drawback by proposing an analysis electronic circuit for passive-matrix multicontact transparent tactile sensors, this analysis electronic circuit being able to measure capacitance and resistance. A multipoint tactile sensor including such an analysis electronic circuit can supply optimum and complete information under all circumstances.

To this end, the present invention proposes an analysis electronic circuit for passive-matrix multicontact tactile sensors including means for electrically energizing one of the two axes of the matrix and means for detecting electrical characteristics on the other axis of the matrix at the intersections between the two axes, characterized in that the electrical characteristic measured is alternately capacitance and resistance.

In particular embodiments of the present invention:
the alternation of the measured electrical characteristic is periodic;
the alternation of the measured electrical characteristic is effected in each scanning cycle.

A multipoint tactile sensor including such an analysis electronic circuit integrates the advantages of capacitance measurement, i.e. high sensitivity making it possible to detect the approach of a finger without necessarily any physical contact with the sensor, which provides early and therefore more subtle contact. This sensor also integrates the advantages of resistance measurement, i.e. the reliability of the measured signal with any contact tool.

In other particular embodiments of the present invention:
the alternation of the measured electrical characteristic is conditioned by the detection of at least one artifact;
the measured electrical characteristic is the resistance in the case of detection of at least one artifact.

A multipoint tactile sensor including such an analysis electronic circuit has the advantage of avoiding all problems of the possibly regular occurrence of artifacts. In such a case, the measurement effected is resistance measurement, which offers greater reliability of the measured information compared to resistance measurement. This sensor is thus able to adapt as a function of the context to supply the best possible tactile information.

In another particular embodiment of the present invention, the alternation of the measured electrical characteristic is conditioned by the reception of a control signal.

A multipoint tactile sensor including such an analysis electronic circuit makes it possible to benefit from adaptation to the type of contact tool of the user, for example. In the case of measurement with a contact tool other than a finger (for example a stylus), resistance measurement will be preferred. In the case of measurement with a finger, capacitance measurement will provide the optimum information.

Thus if the user employs a stylus, for example, he can activate a control signal delivering information to the multipoint tactile sensor in order for the latter to function in a resistance measurement mode. If he uses a finger, on the other hand, no such signal will be delivered and the multipoint tactile sensor will function in a resistance measurement mode.

In another particular embodiment of the present invention, the electrical characteristic measured in each scanning phase of the sensor is resistance. When contact is detected in a contact area an additional capacitance measurement is effected over said area as a whole in order to determine the nature of said contact. Thus it is possible to identify if the contact is with a finger (or any other part of the hand) or some other object (for example a stylus). If it is a finger or another part of the hand, the capacitance measured will be different from the reference capacitance of the sensor. In the case of a stylus, on the other hand, the measured capacitance will be unchanged. Accordingly, in this embodiment of the present invention, it is possible to associate a specific identifier with each new cursor as a function of the type of contact (see the figure). This technique in particular makes it possible to associate specific processing laws with the graphic objects as a function of the contact means.

In another particular embodiment of the present invention for which the contact means is a finger, the electrical characteristic measured in each phase of scanning the sensor is resistance. If contact is detected in a contact area during a scanning phase and is no longer detected during a later scanning phase, an additional capacitance measurement is effected in said area as a whole in order to determine any subsequent proximity of this finger.

In another particular embodiment of the present invention the electrical characteristic measured in each phase of scanning the sensor is capacitance. If contact is detected in a contact area inside a graphic object, an additional resistance measurement is effected over the whole of said graphic object in order to determine the force exerted on said graphic object by said contact. This makes it possible, for example, to confirm whether a contact is intentional or not. It is possible thanks to this technique to distinguish between stroking and pressing.

The present invention also concerns a multicontact passive-matrix tactile sensor including means for electrically energizing one of the two axes of the matrix and means for detecting electrical characteristics on the other axis of the matrix at the intersections between the two axes, said tactile sensor also including an analysis electronic circuit of any of the above embodiments of the present invention.

Thus such a sensor has three modes of operation each having its own advantages: a periodic mode, a mode conditioned by artifact detection, and a mode conditioned by reception of a command signal.

These three modes can be combined to benefit from the advantages of each mode. In each case, the modes are assigned relative priorities. More particularly, the mode conditioned by the reception of a control signal may take priority over the mode conditioned by artifact detection, which itself may take priority over the periodic mode.

The present invention will be better understood on reading the detailed description of a nonlimiting embodiment of the present invention accompanied by appended figures respectively showing:

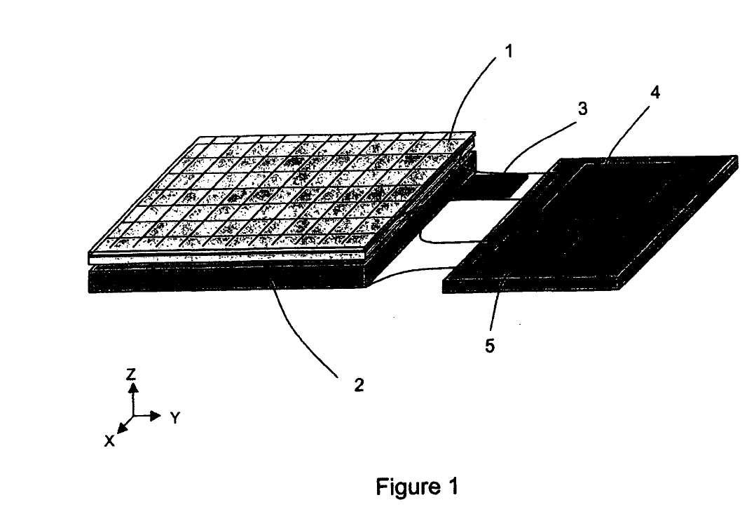

FIG. 1, a view of a passive-matrix multicontact tactile display,

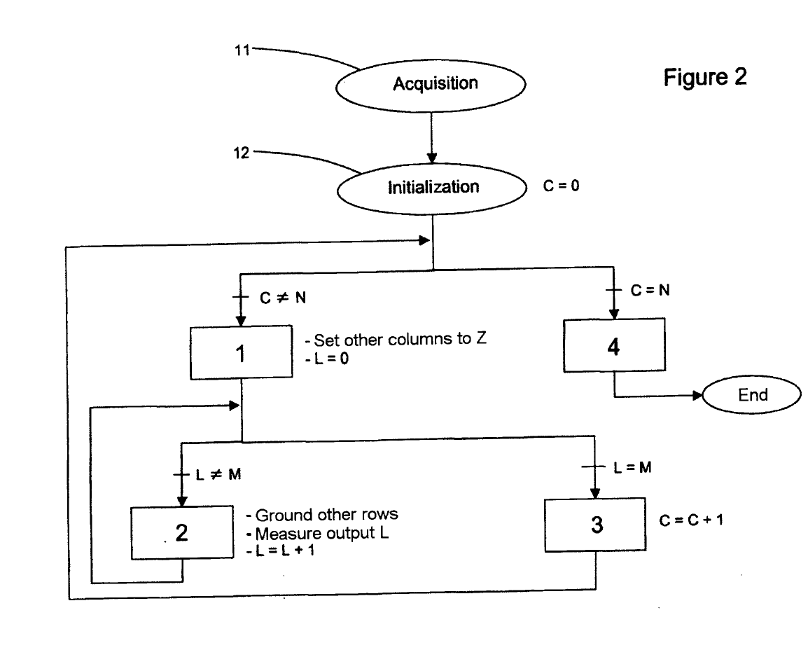

FIG. 2, a diagram of a method of acquisition of data over the whole of the tactile sensor used by an electronic circuit of the present invention,

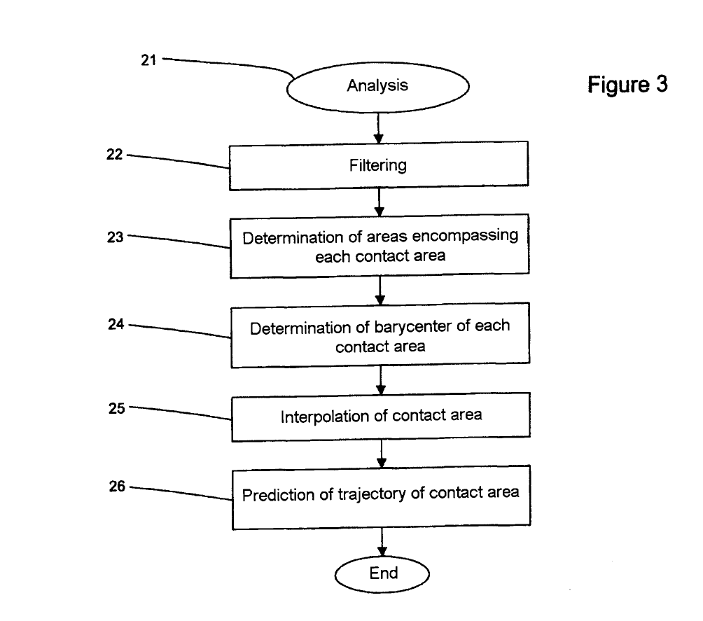

FIG. 3, a diagram of a data analysis method used by an electronic circuit of the present invention,

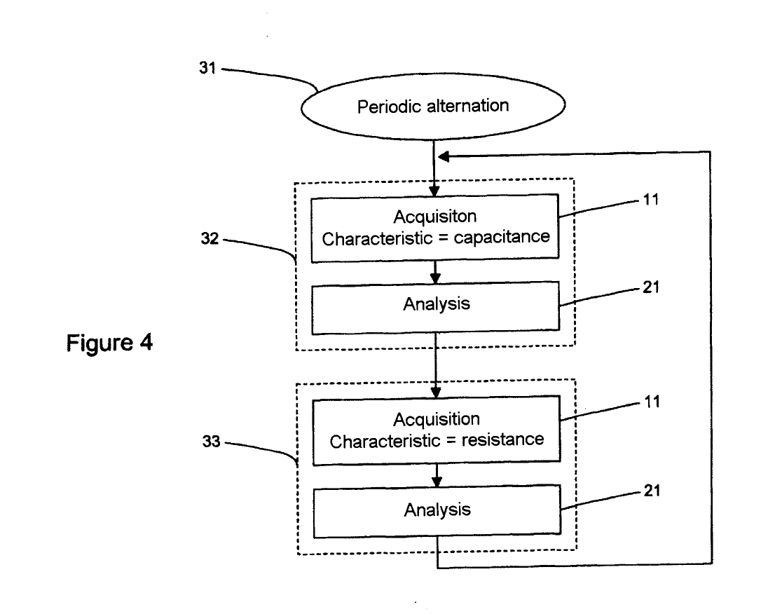

FIG. 4, a diagram of an acquisition and analysis method used by an electronic circuit of a first embodiment of the present invention, this method including periodic capacitance/resistance alternation,

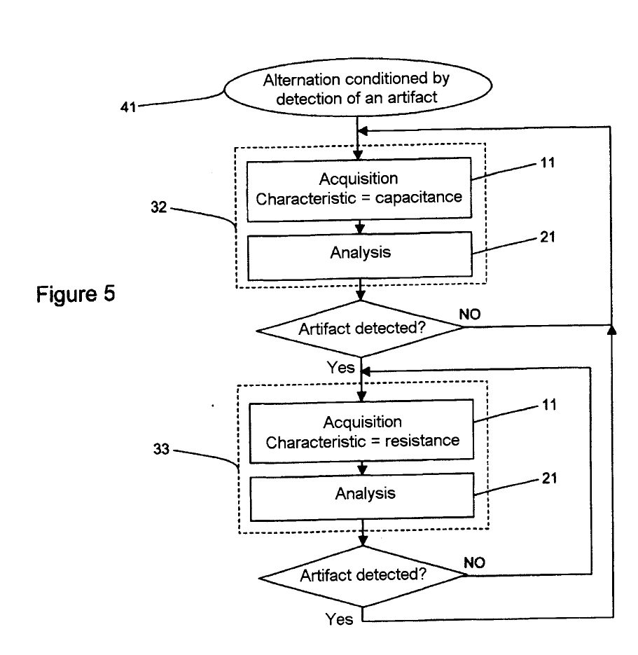

FIG. 5 is a diagram of an acquisition and analysis method used by an electronic circuit of a second embodiment of the present invention, this method including capacitance/resistance alternation conditioned by the detection, if any, of an artifact,

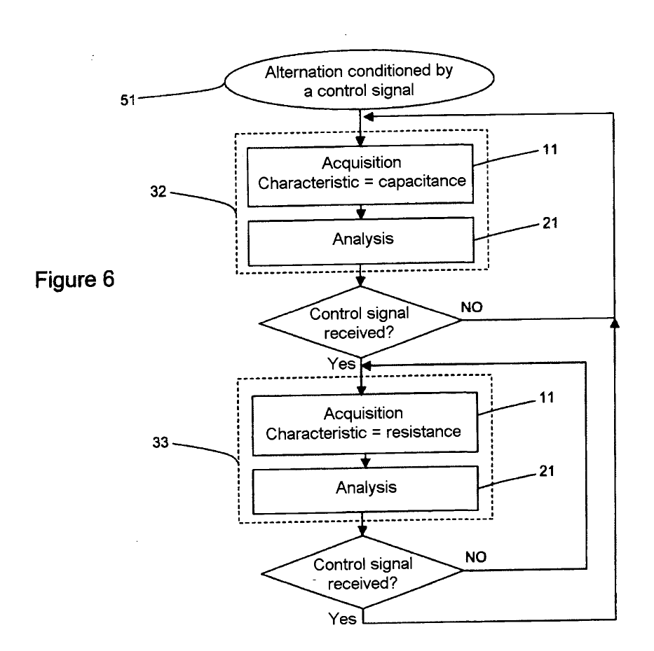

FIG. 6, a diagram of an acquisition and analysis method used by an electronic circuit of a third embodiment of the present invention, this method including capacitance/resistance alternation conditioned by the reception of a control signal,

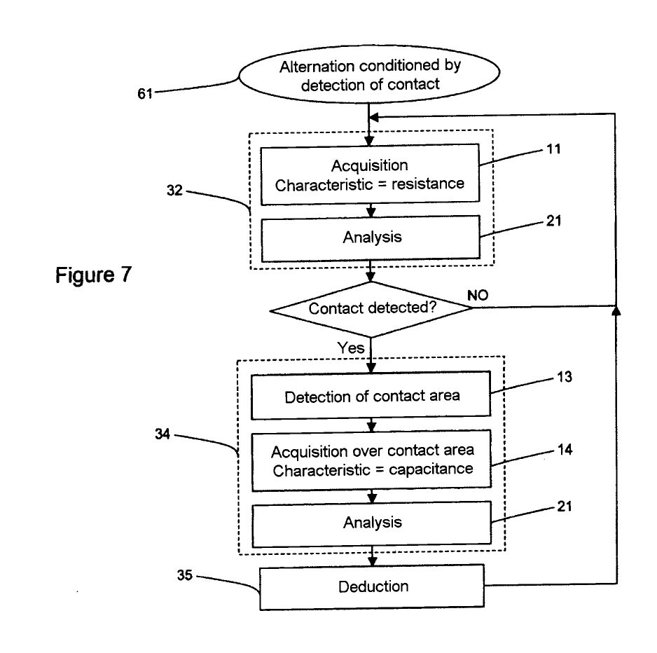

FIG. 7, a diagram of an acquisition and analysis method used by an electronic circuit of a fourth embodiment of the present invention, this method including capacitance/resistance alternation conditioned by the reception of a control signal,

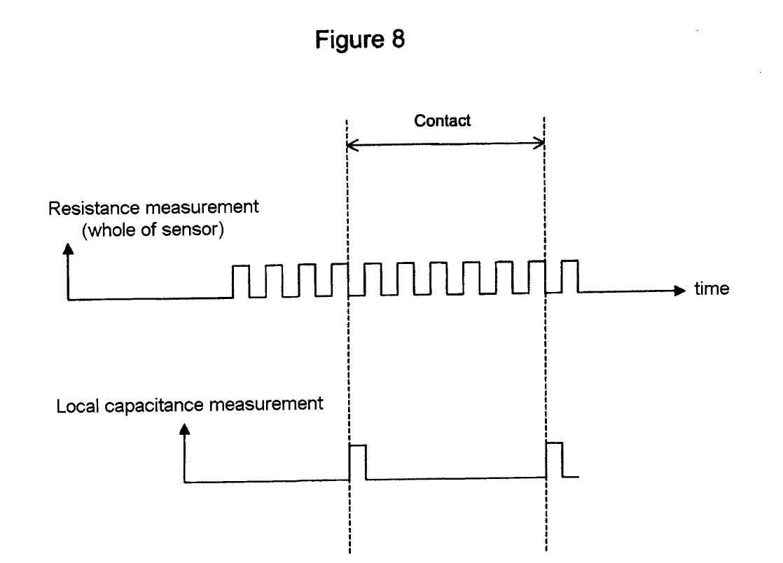

FIG. 8, a timing diagram relating to the detection of contact by the method of the fourth embodiment of the present invention,

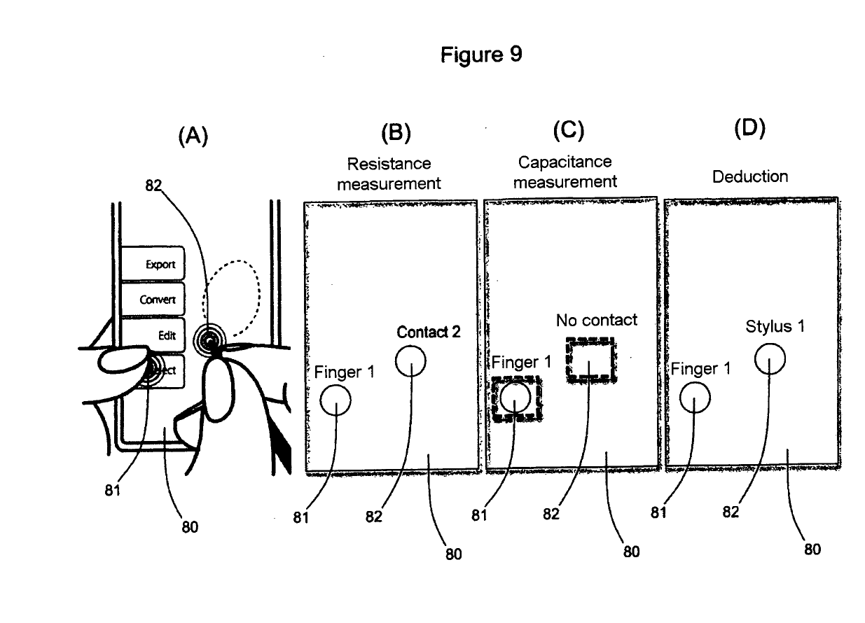

FIGS. 9A to 9D, diagrams of a tactile screen during contact in the method of the fourth embodiment of the present invention,

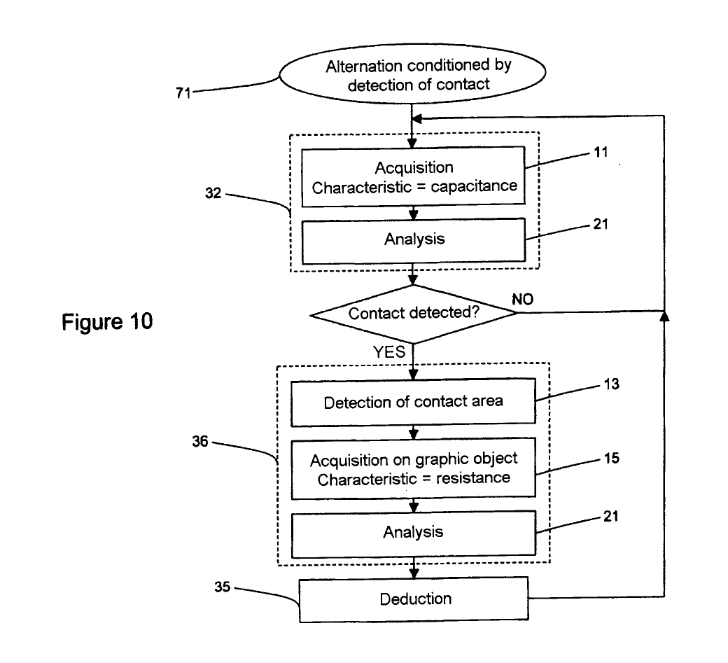

FIG. 10, a diagram of an acquisition and analysis method used by an electronic circuit of a fifth embodiment of the present invention, this method including capacitance/resistance alternation conditioned by the reception of a control signal,

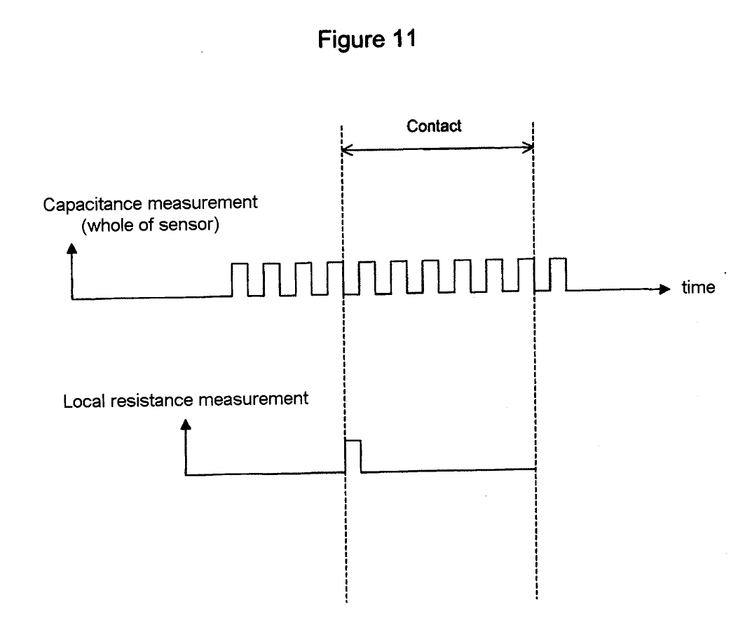

FIG. 11, a timing diagram relating to the detection of contact by the method of the fifth embodiment of the present invention, and

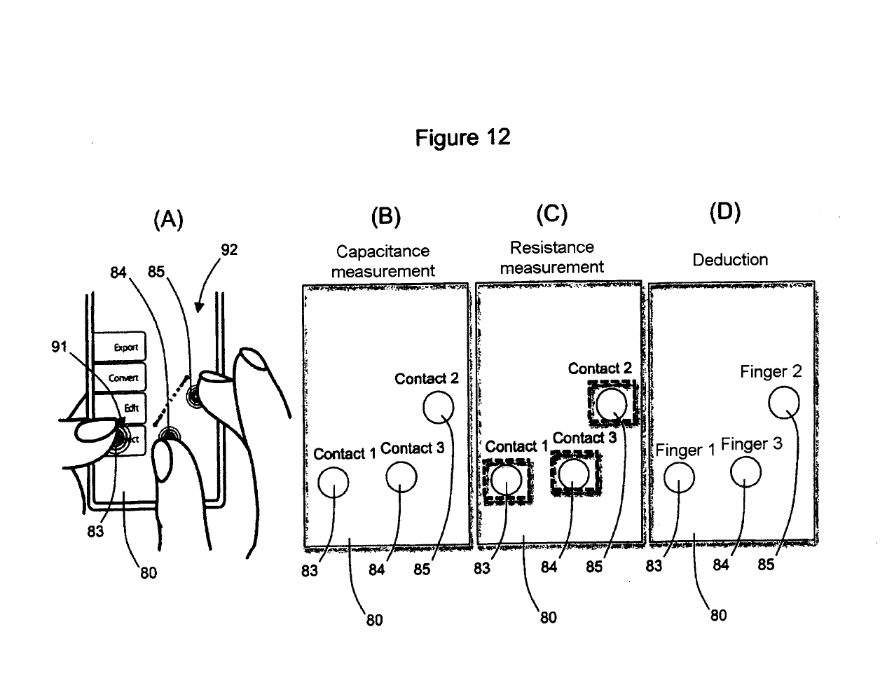

FIGS. 12A to 12D, diagrams of a tactile screen during contact in the method of the fifth embodiment of the present invention.

An electronic analysis circuit of the present invention is intended to be integrated into a passive-matrix multicontact tactile sensor.

FIG. 1 represents a view of a tactile electronic device including:
a matrix tactile sensor 1,
a display screen 2,
a capture interface 3,
a main processor 4, and
a graphics processor 5.

The first fundamental element of said tactile device is the tactile sensor 1, necessary for acquisition—multicontact manipulation—with the aid of a capture interface 3. This capture interface 3 contains the acquisition and analysis electronic circuits.

Said tactile sensor 1 is of matrix type. Said sensor can be divided into a number of parts to accelerate capture, each part being scanned simultaneously.

The data from the capture interface 3 is transmitted after filtering to the main processor 4. The latter executes the local program for associating data from the tablet with graphic objects displayed on the screen 2 in order to be manipulated.

The main processor 4 also transmits to the graphical interface the data to be displayed on the display screen 2. This graphical interface may further be controlled by a graphics processor 5.

The tactile sensor is controlled in the following manner: during a first scanning phase, the tracks of one of the arrays are energized successively and the response on each of the tracks of the second array is detected. Contact areas that correspond to the nodes whose state is modified compared to the idle state are determined as a function of these responses. One or more sets of adjacent nodes whose state has been modified are determined. A set of such adjacent nodes defines a contact area. Position information is calculated from this node system that is referred to as a cursor in relation to the present patent. In the case of a plurality of sets of nodes separated by non-active areas, a plurality of independent cursors will be determined during the same scanning phase.

This information is refreshed periodically during new scanning phases.

The cursors are created, tracked or destroyed as a function of the information obtained during successive scans. For example, the cursor is calculated by a contact area barycenter function.

The general principle is to create as many cursors as there are areas detected on the tactile sensor and to track their evolution in time. When the user removes his fingers from the sensor, the associated cursors are destroyed. In this way, it is possible to capture the position and evolution of a plurality of fingers on the tactile sensor simultaneously.

The electrical characteristic actually measured may be the resistance or the capacitance.

When it is wished to know if a row has been brought into contact with a column, determining a point of contact on the sensor 1, electrical characteristics—voltage, capacitance or inductance—are measured at the terminals of each node of the matrix.

The main processor 4 executes the program for associating the data from the sensor with graphic objects that are displayed on the display screen 2 in order to be manipulated.

FIG. 2 represents a diagram of the method 11 of acquisition of data over the whole of the tactile sensor used by the electronic circuit, with the columns as the energization axis and the rows as the detection axis. The sensor comprises M rows and N columns.

The function of this method is to determine the state of each node of the matrix sensor 1, namely whether said node is activated or not.

Said method corresponds to measuring all the nodes of a “voltage” matrix. Said matrix is an [N,M] matrix containing at each point (I,J) the value of the voltage measured at the terminals of the point of intersection of the row I and the column J, with 1≦I≦N and 1≦J≦M. This matrix makes it possible to give the state of each of the points of the matrix sensor 1 at a given time.

The acquisition method 11 begins with a step 12 of initialization of the data obtained during a previous acquisition.

The column axis constitutes the energization axis and the row axis constitutes the detection axis. In another embodiment of the present invention, the row axis constitutes the energization axis and the column axis constitutes the detection axis.

The method 11 first scans the first column. It is energized at 5 volts, for example. For said column, the electronic circuit measures an electrical characteristic at the point of intersection between said column and each of the rows from 1 to N.

When the measurement has been effected on the N^{th} row, the method proceeds to the next column and resumes the measurements of electrical characteristics at the intersection of the new column concerned and each of the rows from 1 to N.

When all the columns have been scanned, the electrical characteristics of each of the points of the matrix sensor 1 have been measured. The method is then terminated and the electronic circuit can proceed to the analysis of the voltage matrix obtained.

FIG. 3 represents a diagram of the method 21 of analysis of the data implemented by the electronic circuit.

Said method 21 consists of a series of algorithms performing the following steps:
one or more filtering steps 22,
determination 23 of the areas encompassing each contact area,
determination 24 of the barycenter of each contact area,
interpolation 25 of the contact area,
prediction 26 of the trajectory of the contact area.

Once the analysis method 21 has ended, the software is able to apply various specific processing operations to the virtual graphic objects of the tactile electronic device in order to refresh said tactile electronic device in real time. Areas encompassing the contact areas detected during the data acquisition step 11 are also defined.

FIG. 4 represents a diagram of an acquisition and analysis method 31 used by an electronic circuit of a first embodiment of the present invention. Said method 31 periodically alternates capacitance and resistance measurements.

In this embodiment of the present invention, the electronic circuit executes the step 32 corresponding to the succession of the acquisition step 11 and the analysis step 21 with the capacitance as the measured electrical characteristic.

Following the step 32, a new step 33 is effected, this step 33 corresponding to the succession of the acquisition step 11 and the analysis step 21, this time with the resistance as the measured electrical characteristic.

The method 31 performs a loop comprising the succession of steps 32 and 33. The latter loop thus makes it possible to alternate measurement of electrical characteristics chosen from capacitance and resistance.

In another variant of this embodiment of the present invention, the method performs the first step 32 K times and then the second step 33 L times, K and L being integers of which at least one is strictly greater than 1.

The refresh frequency is of the order of 100 Hz, for example.

FIG. 5 represents a diagram of an acquisition and analysis method 41 used by an electronic circuit of a second embodiment of the present invention. Said method alternates capacitance and resistance measurement, said alternation being conditioned by the detection, if any, of an artifact.

In this embodiment of the present invention, the method 41 performs the steps 32 and 33.

Going from one to the other of the steps 32 and 33 is conditioned by the detection, if any, of an artifact resulting from each of the analysis steps 21 performed in the steps 32 and 33.

Each time the step 21 performed during the step 32 or 33 ends, the electronic circuit determines if a spurious phenomenon of artifact type is present on at least part of the matrix sensor 1 for which the state data for each of the nodes has been acquired and analyzed. If no artifact has been detected on exit from the step 32 or 33, then the method loops to the same step. If an artifact has been detected, then the method alternates the step.

For example, if no artifact has been detected on exit from the step 32, the method loops to said step 32, but if an artifact has actually been detected, the method alternates to the step 33.

FIG. 6 represents a diagram of an acquisition and analysis method 51 used by an electronic circuit of a third embodiment of the present invention. Said method 51 alternates capacitance and resistance measurement, said alternation being conditioned by a control signal.

In this embodiment of the present invention, the method performs the steps 32 and 33.

The change from one to the other of the steps 32 and 33 is conditioned by a control signal.

Each time the step 21 executed during the step 32 or 33 ends, the electronic circuit determines if it has received a control signal between said step and the preceding step. If no control signal has been received, then the method loops to the same step. If a control signal has been received, then the method alternates to the other step.

For example, if a control signal has been received on exit from the step 32, the method loops to said step 32, but if a control signal has actually been received, the method alternates to the step 33.

Such a control signal can be activated by the user of the multipoint tactile electronic device, for example. This user can use capacitance measurement only if his contact tool is a finger. If not, he is constrained to use resistance measurement. Thus if the user is using a stylus, for example, he can activate a control signal delivering information to the multipoint tactile sensor 1 in order for the latter to function in a resistance measurement mode.

In a fourth embodiment of the present invention illustrated by FIGS. 7 to 9, the characteristic measured in each scanning phase is resistance, measured point by point over the whole of the sensor (step 32). Information is then obtained as to the existence of a contact, if any. If contact is detected at one point at least, the characteristic measured becomes the capacitance for one measurement, over a block of points contained within the sensor (step 34). This block corresponds to the cursor created after detection of contact in resistance mode (step 13). Capacitance measurement (step 14) at this cursor—or contact area—then provides, after analysis (step 21) and deduction (step 35), information as to the nature of the contact, namely whether the contact means is a finger (detected by a capacitance measurement) or a stylus (not detected by a capacitance measurement).

Referring to FIGS. 9A and 9B, a first contact 81 with a finger and a second contact 82 on the tactile screen 80 with a stylus are detected during a resistance measurement. As FIG. 9C and the FIG. 8 timing diagram show, there then follows capacitance measurement at these two contact areas 81 and 82. This measurement makes it possible to detect contact in the area of the first contact 81 (finger) and produces no detection in the area of the second contact 82 (stylus). As shown in FIG. 9D, it is thus possible to discriminate the two types of contact, i.e. a finger 1 for the first contact 81 and a stylus 1 for the second contact 82.

This capacitance measurement is effected once only on this created cursor (FIG. 8), the nature of the contact with this cursor being a priori unable to change while contact is maintained, and resistance mode scanning phases are carried out in parallel.

This variant of the analysis electronic circuit makes it possible to determine the nature of the contact in order to take account of it, for example to adapt the accuracy of the next resistance measurement—the resolution must be higher for a stylus—or to reject a contact if its nature is not that which the tactile sensor or a portion thereof is able to tolerate.

In a variant analogous to this fourth embodiment of the present invention, in the case of contact by a finger, while contact is detected, the measurements are effected in resistance mode for the whole of the sensor, point by point, in each scanning phase. If releasing of the cursor corresponding to this contact is detected, there follows capacitance measurement over the area of the sensor in a block. This measurement makes it possible to determine if the finger is still in the proximity of the released contact area, which is a sign of unintentional releasing of the finger during prolonged contact (for example during manipulation of a graphic object corresponding to a scrolling window).

This variant of the analysis electronic circuit thus makes it possible not to lose a cursor defined by a finger if such loss of the cursor was not intentional.

In a fifth embodiment of the present invention illustrated by FIGS. 10 to 12, a graphic object is made secure. To this end, a capacitance measurement is effected over a graphic object to be made secure, point by point, in each scanning phase (step 32). If contact is detected in this capacitance mode, there follows detection of the contact area (step 13) and then measurement in resistance mode (step 15) over the whole of the graphic object, which makes it possible to obtain after analysis (step 21) information as to the force exerted by the contact detected. There follows the next deduction step (step 35): if this force does not exceed a threshold value, the contact is insufficient and is not considered as a contact leading to the creation of a cursor. Otherwise the cursor is created.

Referring to FIGS. 12A and 12B, three finger contacts 83 (graphic object 91), 84 and 85 (graphic object 92) are detected on the tactile screen 80 during capacitance measurement. As FIG. 12C and the FIG. 11 timing diagram show, there follows resistance measurement over the graphic object 91 or 92 associated with each contact area. This measurement makes it possible to detect contact in the areas of the three contacts 83, 84 and 85. As shown in FIG. 12D, it is thus possible to validate the fact that the three contacts are intentional contacts and not accidental. Moreover, if another contact had been detected on the tactile screen 80 during the capacitance measurement, corresponding for example to a stroking contact, the latter would not have been detected during the resistance measurement and would therefore not have been validated.

The resistance measurement on this created cursor (FIG. 11) is effected only once, the nature of the contact consisting of this cursor being unable a priori to change for as long as contact is maintained, and capacitance mode scanning phases are effected in parallel.

This variant of the analysis electronic circuit makes it possible to prevent an involuntary contact—for example a stroking contact—being taken into account for a graphic object the activation or non-activation of which by contact is of fundamental importance.

A multipoint tactile sensor integrating an analysis electronic circuit of any of the embodiments of the present invention described above has the advantage of combining the advantages of capacitance measurement—which include “touch” sensitivity—and resistance measurement—adaptation to any type of contact tool—without being constrained by their respective drawbacks.

Such a multipoint tactile sensor is therefore capable of providing optimum and complete information in any circumstances.

The embodiments of the present invention described above are provided by way of example and are in no way limiting on the present invention. It is understood that the person skilled in the art is in a position to produce different variants of the present invention without departing from the scope of the patent.

1-10. (canceled)

11. An analysis electronic circuit for a passive-matrix multicontact tactile sensors comprising:
means for electrically energizing one of two axes of the matrix; and
means for detecting electrical characteristics on the other axis of the matrix at intersections between the two axes,
wherein the electrical characteristic measured is alternately capacitance and resistance.

12. An analysis electronic circuit according to claim 11, wherein the alternation of the measured electrical characteristic is periodic.

13. An analysis electronic circuit according to claim 12, wherein the alternation of the measured electrical characteristic is effected in each of a scanning cycle.

14. An analysis electronic circuit according to claim 11, wherein the alternation of the measured electrical characteristic is conditioned by detection of at least one artifact.

15. An analysis electronic circuit according to claim 14, wherein the measured electrical characteristic is the resistance in a case of detection of the at least one artifact.

16. An analysis electronic circuit according to claim 11, wherein the alternation of the measured electrical characteristic is conditioned by reception of a control signal.

17. An analysis electronic circuit according to claim 11, wherein the electrical characteristic is measured in each of a scanning phase of the sensor and is resistance, and when a contact is detected in a contact area an additional capacitance measurement is effected over an area as a whole to determine a nature of the contact.

18. An analysis electronic circuit according to claim 11, for which the contact means is a finger, wherein the electrical characteristic measured in each of a phase of scanning the sensor is resistance, and if contact is detected in a contact area during a first scanning phase and is no longer detected during a later scanning phase, an additional capacitance measurement is effected over an area as a whole to determine any subsequent proximity of the finger.

19. An analysis electronic circuit according to claim 11, wherein the electrical characteristic is measured in each of a phase of scanning the sensor and is capacitance, and if contact is detected in a contact area inside a graphic object, an additional resistance measurement is effected over a whole of the graphic object to determine a force exerted on the graphic object by the contact.

20. A multicontact passive-matrix tactile sensor comprising:
means for electrically energizing one of two axes of the matrix; and
means for detecting electrical characteristics on the other axis of the matrix at intersections between the two axes; and
an analysis electronic circuit according to claim 11.
